(19) United States
(12) Patent Application Publication
(10) Pub. No.: US 2024/0092701 A1
(43) Pub. Date: Mar. 21, 2024

(54) CERAMIC SINTERED BODY SUBSTRATE, LIGHT-EMITTING DEVICE, AND MANUFACTURING METHODS THEREOF

(71) Applicant: NICHIA CORPORATION, Anan-shi (JP)

(72) Inventors: Masaaki KATSUMATA, Anan-shi (JP); Eiko MINATO, Anan-shi (JP); Takashi KAWAMATA, Anan-shi (JP); Akiko NAGAE, Komatsushima-shi (JP)

(73) Assignee: NICHIA CORPORATION, Anan-shi (JP)

(21) Appl. No.: 18/468,650

(22) Filed: Sep. 15, 2023

(30) Foreign Application Priority Data
Sep. 16, 2022 (JP) 2022-148503
Jul. 18, 2023 (JP) 2023-117096

(51) Int. Cl. C04B 41/51; C04B 37/00; C04B 41/00; C04B 41/45; C04B 41/53; H01L 33/62

(52) U.S. Cl. CPC C04B 41/5183; C04B 37/006; C04B 41/0072; C04B 41/4521; C04B 41/5307; H01L 33/62; C04B 2237/12; H01L 2933/0066

(57) ABSTRACT

A method for manufacturing a ceramic sintered body substrate includes of disposing a first metal paste on a surface of a ceramic substrate, and of firing the ceramic substrate on which the first metal paste is disposed. In the disposing the first metal paste, the first metal paste contains a plurality of first metal powders, a plurality of active metal powders, and a plurality of inorganic fillers excluding metals, and in the firing the ceramic substrate, a firing temperature is equal to or higher than a melting point of the first metal powders.

### CROSS-REFERENCE TO RELATED APPLICATIONS

The present application claims priority under 35 U.S.C. § 119 to Japanese Patent Application No. 2022-148503, filed Sep. 16, 2022, and Japanese Patent Application No. 2023-117096, filed Jul. 18, 2023, the contents of which are hereby incorporated by reference in their entirety.

### BACKGROUND

### 1. Technical Field

The present disclosure relates to a ceramic sintered body substrate, a light-emitting device, and manufacturing methods thereof.

### 2. Description of Related Art

In the related art, a via material used for a ceramic substrate includes a through conductor containing silver and copper as main components, and the through conductor is known to include a eutectic region of silver and copper in a metal layer side region in a center region of a diameter and a non-eutectic region of silver and copper in a central region in the center region of the diameter. As the via material used for the ceramic substrate, a via material is known which is obtained by being filled with a first metal paste containing a powder of a metal B having a higher melting point than a metal A having a melting point in a range from 600° C. to 1100° C. and an active metal, and layering a second metal paste containing a powder of the metal A at a position in contact with the first metal paste (for example, see Japanese Patent No. 6122561 and Japanese Patent No. 5922739).

### SUMMARY

An object of an embodiment according to the present disclosure is to provide a ceramic sintered body substrate having high connection stability by reduction in volume shrinkage of a via material, a light-emitting device, and manufacturing methods thereof.

A method for manufacturing a ceramic sintered body substrate disclosed in an embodiment includes disposing a first metal paste on a surface of a ceramic substrate; and firing the ceramic substrate on which the first metal paste is disposed. In the disposing the first metal paste, the first metal paste contains a plurality of first metal powders, a plurality of active metal powders, and a plurality of inorganic fillers excluding metals. In the firing the ceramic substrate, a firing temperature is equal to or higher than a melting point of the first metal powder.

A method for manufacturing a light-emitting device disclosed in an embodiment includes preparing a ceramic sintered body substrate manufactured by the method for manufacturing a ceramic sintered body substrate, according to the above embodiment; and disposing a light-emitting element on the ceramic sintered body substrate. In the preparing the ceramic sintered body substrate, the first metal paste becomes a first metal member by firing. In the disposing the light-emitting element, the first metal member is directly or indirectly electrically connected to the light-emitting element.

A method for manufacturing a light-emitting device disclosed in an embodiment includes preparing a ceramic sintered body substrate manufactured by the method for manufacturing a ceramic sintered body substrate, according to the above embodiment; and disposing a light-emitting element on the ceramic sintered body substrate. In the preparing the ceramic sintered body substrate, the first metal paste becomes a first metal member by firing and the second metal paste becomes a second metal member by the firing. In the disposing the light-emitting element, the first metal member or the second metal member is directly or indirectly electrically connected to the light-emitting element.

A ceramic sintered body substrate disclosed in an embodiment includes a ceramic substrate; and a first metal member disposed on a surface of the ceramic substrate. The first metal member contains a plurality of inorganic fillers, a first metal, and a metal compound. The metal compound is disposed on at least a part of surfaces of the plurality of inorganic fillers and at least a part of a surface of the ceramic substrate.

A light-emitting device disclosed in an embodiment includes a ceramic sintered body substrate including a ceramic substrate and a first metal member disposed on a surface of the ceramic substrate, the first metal member containing a plurality of inorganic fillers, a first metal, and a metal compound, the metal compound being disposed on at least a part of surfaces of the plurality of inorganic fillers and at least a part of a surface of the ceramic substrate; and a light-emitting element electrically connected to the first metal member of the ceramic sintered body substrate.

A light-emitting device disclosed in an embodiment includes a ceramic sintered body substrate including a ceramic substrate and a first metal member and a second metal member disposed on a surface of the ceramic substrate, the first metal member containing a plurality of inorganic fillers, a first metal, and a metal compound, the metal compound being disposed on at least a part of surfaces of the plurality of inorganic fillers and at least a part of a surface of the ceramic substrate; and a light-emitting element electrically connected to the first metal member or the second metal member of the ceramic sintered body substrate.

An embodiment of the present disclosure can provide a ceramic sintered body substrate having high reliability by reduction in volume shrinkage of a via material, a light-emitting device, and manufacturing methods thereof.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a plan view schematically illustrating a ceramic sintered body substrate according to an embodiment.

FIG. 2 is a cross-sectional perspective view schematically illustrating a cross-section taken along line II-II of FIG. 1.

FIG. 3A is an enlarged cross-sectional view schematically illustrating a state in which a through hole of the ceramic sintered body substrate according to the embodiment is filled with a first metal paste.

FIG. 3B is an enlarged cross-sectional view schematically illustrating a state of a first metal member after the ceramic sintered body substrate in FIG. 3A is sintered.

FIG. 4 is a flowchart exemplifying a method for manufacturing the ceramic sintered body substrate according to the embodiment.

FIG. 5A is a cross-sectional view schematically illustrating a prepared ceramic substrate in the method for manufacturing the ceramic sintered body substrate according to the embodiment.

FIG. 5B is a cross-sectional view schematically illustrating a state in which the through hole is filled with the first metal paste in the method for manufacturing the ceramic sintered body substrate according to the embodiment.

FIG. 5C is a cross-sectional view schematically illustrating a state in which second metal pastes are disposed in the method for manufacturing the ceramic sintered body substrate according to the embodiment.

FIG. 6 is a cross-sectional view schematically illustrating a light-emitting device according to an embodiment.

FIG. 7 is a flowchart exemplifying a method for manufacturing the light-emitting device according to the embodiment.

FIG. 8A is a cross-sectional view schematically illustrating a prepared ceramic sintered body substrate in the method for manufacturing the light-emitting device according to the embodiment.

FIG. 8B is a cross-sectional view schematically illustrating a state in which a bonding member is disposed on the ceramic sintered body substrate in the method for manufacturing the light-emitting device according to the embodiment.

FIG. 8C is a cross-sectional view schematically illustrating a state in which a light-emitting element is disposed in the method for manufacturing the light-emitting device according to the embodiment.

FIG. 8D is a cross-sectional view schematically illustrating a state in which a light reflective member is disposed in the method for manufacturing the light-emitting device according to the embodiment.

FIG. 9A is a perspective view illustrating the light-emitting device according to the embodiment as a light-emitting module.

FIG. 9B is a cross-sectional view schematically illustrating a cross-section taken along line IXB-IXB with a part of FIG. 9A omitted.

### DETAILED DESCRIPTION

### Description of Embodiments

Embodiments according to the present disclosure are described below with reference to the drawings. However, the embodiments described below are merely intended to embody the technical concept according to the present disclosure, and the invention is not limited to the following description unless otherwise specified. The content described in one embodiment can also be applied to another embodiment or modified example. The drawings are diagrams that schematically illustrate the embodiments. In order to provide clarity in the description, scales, intervals, positional relationships, and the like of members may be exaggerated, or some of the members may be omitted in the drawings. Directions illustrated in the drawings indicate relative positions between constitution components and are not intended to indicate absolute positions. Note that members having the same names and reference signs, as a rule, represent the same members or members of the same quality, and detailed description thereof is omitted as appropriate. In the embodiments, “covering” includes not only a case of covering by direct contact but also a case of indirectly covering, for example, via another member.

Ceramic Sintered Body Substrate

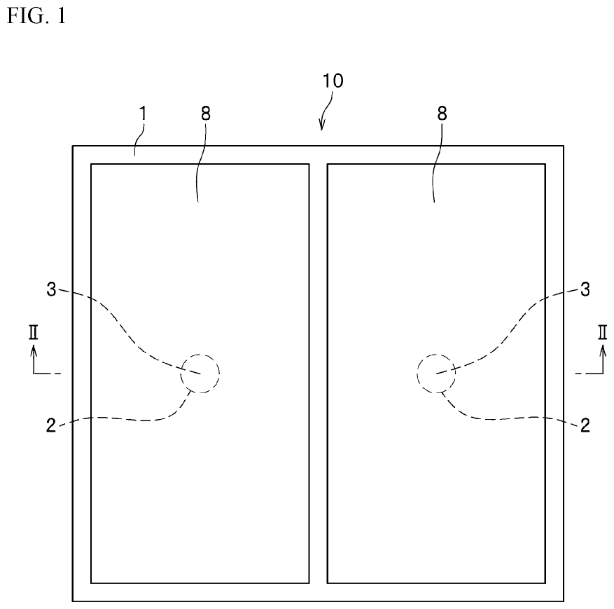

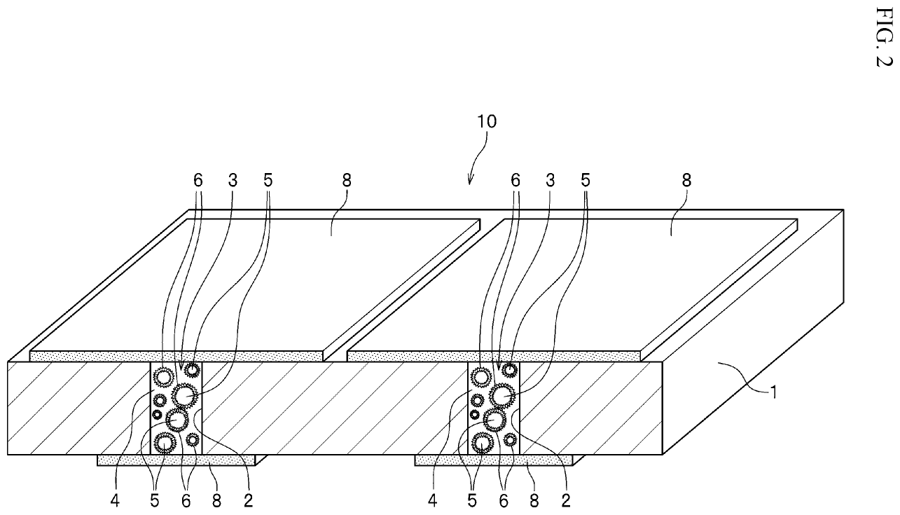

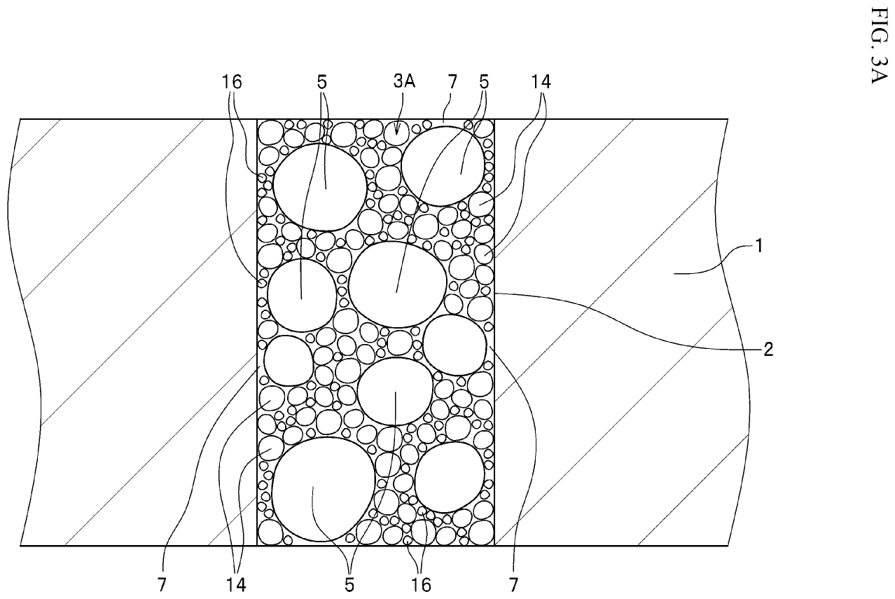

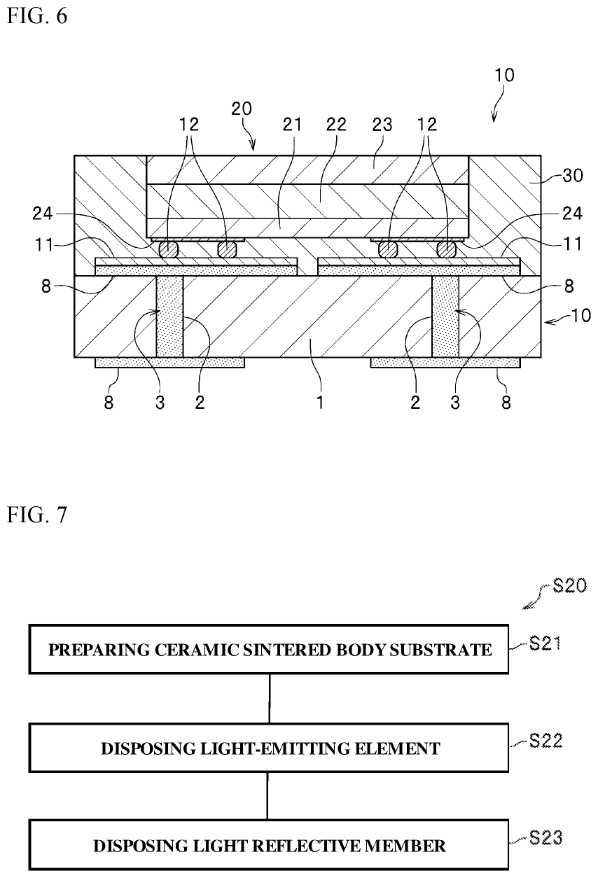

A ceramic sintered body substrate 10 according to an embodiment is described with reference to FIGS. 1, 2, 3A, 3B, and 6. FIG. 1 is a plan view schematically illustrating the ceramic sintered body substrate according to the embodiment, and FIG. 2 is a cross-sectional perspective view schematically illustrating the ceramic sintered body substrate according to the embodiment. FIG. 3A is an enlarged cross-sectional view schematically illustrating a state in which a through hole of the ceramic sintered body substrate according to the embodiment is filled with a first metal member. FIG. 3B is an enlarged cross-sectional view schematically illustrating a state in which a first metal paste has become a first metal by sintering of the ceramic sintered body substrate in FIG. 3A. FIG. 6 is a cross-sectional view schematically illustrating a light-emitting device according to an embodiment. Note that FIG. 3A illustrates a state before the ceramic sintered body substrate is sintered.

The ceramic sintered body substrate 10 includes a ceramic substrate 1 and a first metal member 3 disposed on a surface of the ceramic substrate 1, and the first metal member 3 includes a plurality of inorganic fillers 5, a first metal 4, and a metal compound 6. The metal compound 6 is disposed on at least a part of each of the surfaces of the plurality of inorganic fillers 5 and the surface of the ceramic substrate 1. The surface of the ceramic substrate 1 includes a flat surface, a bottom surface, and a lateral surface of the ceramic substrate 1, and when a through hole, a stepped portion, or a recessed portion is provided, the surface of the ceramic substrate 1 also includes an inner lateral surface and the like thereof. Unless otherwise specified, the term “surface” in the specification refers to “surface” and does not refer to “front surface”.

Note that the ceramic sintered body substrate 10 is described as including the first metal member 3 disposed in a through hole 2 of the ceramic substrate 1 and second metal members 8 disposed on the first metal member 3. However, the first metal member may be referred to as a first metal paste before firing, and the second metal member may be referred to as a second metal paste before firing. Although the state of a fired product is different from that of a raw material, the fired product may be expressed by the name of the raw material for convenience of explanation. Although the ceramic substrate has different properties before and after firing, it is described as a ceramic substrate.

Components of the ceramic sintered body substrate 10 are described below.

Ceramic Substrate

The ceramic substrate 1 is a member having a plate shape and serving as a base of the ceramic sintered body substrate 10. The ceramic substrate 1 has, for example, a rectangular shape in the plan view. Note that the shape of the ceramic substrate 1 in the plan view is not particularly limited. The ceramic substrate 1 is preferably at least one selected from silicon nitride, aluminum nitride, and boron nitride. Note that the ceramic substrate 1 is preferably made of a nitride ceramic such as silicon nitride, aluminum nitride, or boron nitride, but may be made of an oxide ceramic such as aluminum oxide, silicon oxide, calcium oxide, or magnesium oxide. The ceramic substrate 1 may be made of silicon carbide, mullite, borosilicate glass, or the like.

In the ceramic substrate 1, for example, the through hole 2 is provided at a predetermined position in a plate thickness direction, and the first metal member 3 is disposed inside the through hole 2. In the ceramic substrate 1, a first metal paste 3A is fired and thereby being disposed as the first metal member 3. Note that the second metal members 8 are in contact with the first metal members 3 disposed in the through hole 2, on a first surface, which is the flat surface of the ceramic substrate 1 and a second surface, which is the bottom surface of the ceramic substrate 1. The second metal members 8 are used as a wiring line, a wiring pad, or an external connection electrode for electrical connection with a light-emitting element 20.

The through hole 2 of the ceramic substrate 1 is a via hole for electrically connecting element electrodes 24 of the light-emitting element 20 to the outside of the ceramic substrate 1 via the first metal member 3 disposed inside the through hole 2. The through hole 2 is formed in a sintered ceramic substrate or a green sheet of a ceramic substrate before firing by mechanical processing such as drilling or laser processing, or is formed in the sintered ceramic substrate by chemical processing such as etching. The through hole 2 preferably has a substantially circular shape or a circular shape when cut horizontally with respect to the ceramic substrate 1. The diameter of the through hole 2 is preferably in a range from 0.05 mm to 0.5 mm. When the diameter of the through hole 2 is equal to or greater than 0.05 mm, precise filling with the first metal member 3 is easily performed. When the diameter of the through hole 2 is equal to or less than 0.5 mm, the through hole 2 can be filled with an appropriate amount of the first metal member 3 while maintaining high strength and a low electric resistance value.

First Metal Member and Second Metal Member

The through hole 2 of the ceramic substrate 1 is filled with the first metal member 3, and the first metal member 3 is disposed on the surface of the ceramic substrate 1. The second metal member 8 is disposed on at least one of the flat surface, the bottom surface, the lateral surface, and the like of the ceramic substrate 1. For example, the first metal member 3 is disposed on the flat surface and/or the bottom surface of the ceramic substrate 1 continuously from the through hole 2. The through hole 2 is filled with the first metal member 3, and the first metal member 3 is exposed from the substrate so as to be flush with the flat surface and the bottom surface of the ceramic substrate 1. The first metal member 3 is a member electrically connected to the light-emitting element 20 alone or together with the second metal member 8. The first metal member 3 is a so-called via material.

For example, the first metal member 3 is disposed in the through hole 2 of the ceramic substrate 1 in a state of the first metal paste 3A before firing, and a part of the first metal member 3 is exposed from the ceramic substrate 1. The first metal paste 3A contains an organic binder 7, for example. When the first metal paste 3A is fired, the organic binder is evaporated, and the first metal member 3 is formed. For example, the first metal member 3 contains the first metal 4, the inorganic fillers 5, and the metal compound 6. In the first metal member 3, for example, when the total amount of the first metal 4, the content of the inorganic fillers 5, and the metal compound 6 is 100 wt %, the content of the inorganic fillers 5 is preferably in a range from 1 wt % to 50 wt %, the content of the first metal 4 is preferably in a range from 40 wt % to 95 wt %, and the content of the metal compound 6 is preferably in a range from 1 wt % to 10 wt %. The content of the inorganic fillers 5 is preferably in a range from 1 wt % to 4.5 wt %, and is more preferably in a range from 1.5 wt % to 4.2 wt %. Note that in a case in which the first metal member 3 is the first metal paste 3A before firing, when the total amount of the inorganic fillers 5, a first metal powder 14, and an active metal powder 16 is 100 wt %, the content of the inorganic fillers 5 is preferably in a range from 1 wt % to 50 wt %, the content of the first metal powder 14 is preferably in a range from 40 wt % to 95 wt %, and the content of the active metal powder 16 is preferably in a range from 0.5 wt % to 15 wt %. The content of the inorganic fillers 5 is preferably in a range from 1 wt % to 4.5 wt %, and is more preferably in a range from 1.5 wt % to 4.2 wt %.

The first metal 4 is a metal member serving as a core of the first metal member 3 together with the inorganic fillers 5 when disposed as the first metal member 3. The first metal 4 is disposed in a state in which the inorganic fillers 5 are dispersed. The first metal 4 is contained as the first metal powder 14 in the first metal member 3 before being fired. The first metal powder 14 is preferably at least one selected from Ag, Cu, an Ag—Cu alloy, a Cu—Zn alloy, and a Cu—Sn alloy. Note that the melting point of the first metal powder 14 is preferably in a range from 700° C. to 1200° C., and is more preferably in a range from 700° C. to 1100° C. When the first metal powder 14 is fired, at least one selected from Ag, Cu, Zn, Sn, an Ag—Cu alloy, a Cu—Zn alloy, and a Cu—Sn alloy is formed as the first metal 4. That is, the type of the first metal 4 is identified by the first metal powder 14 used. When the first metal 4 contains the inorganic fillers 5 having a predetermined size in a predetermined range within a predetermined content range, the inorganic fillers 5 can be dispersed in the first metal 4 that is continuous. Note that a plurality of first metal powders 14 indicate that the first metal powder 14 is not one particle but a plurality of particles.

The inorganic fillers 5 are disposed in a state in which a plurality of particles are dispersed in the first metal member 3. The plurality of inorganic fillers 5 indicate that the inorganic fillers 5 are not one particle but a plurality of particles. For example, the median diameter of one particle of the inorganic filler 5 is preferably in a range from 1 μm to 50 μm, and is more preferably in a range from 2 μm to 15 μm. Examples of the inorganic fillers 5 include ceramic fillers such as aluminum oxide and aluminum nitride, silica fillers, metal fillers, and glass fillers. In particular, the inorganic fillers 5 are preferably a material having a linear expansion coefficient of 8 ppm/K or less. Thus, the linear coefficient of the first metal member 3 can be lowered and thermal shock characteristics can be improved. Moreover, the thermal conductivity of the inorganic fillers 5 is preferably 20 W/mK or more, and is more preferably 30 W/mK or more (both at a measurement temperature of 300 K). The inorganic fillers 5 are preferably any one of aluminum nitride (AlN), silicon nitride (Si₃N₄), aluminum oxide (Al₂O₃), silicon carbide (SiC), and the like, for example. By employing these inorganic fillers having high thermal conductivity, the thermal conductivity of the first metal member 3 can be improved. The inorganic fillers 5 are preferably disposed in a range from 10 μm² to 75 μm² per 100 μm² in a cross-sectional view in which the first metal member 3 is cut in the thickness direction of the ceramic substrate 1.

The inorganic fillers 5 are a high thermal conductive member and are contained in the first metal member 3 at a predetermined proportion, so that the volume shrinkage of the first metal member 3 in the through hole 2 can be reduced. Note that by setting the size of the inorganic filler 5 within a predetermined range, the effect of reducing the volume shrinkage of the first metal member 3 is further enhanced. When the inorganic fillers 5 have a predetermined size and a predetermined content, the inorganic fillers 5 are dispersed better in the first metal 4. The inorganic fillers 5 are preferably a material having a low linear expansion coefficient of 5 ppm/K or less and a high thermal conductivity of 100 W/m·K or more, such as AlN, Si₃N₄, or SiC. By dispersing the inorganic fillers 5 in the first metal 3, the difference in linear expansion coefficient between the ceramic substrate 1 and the inorganic fillers 5 can be reduced and the reliability such as thermal shock characteristics can be improved. Furthermore, by adding AlN, Si₃N₄, SiC, or the like having high thermal conductivity, the thermal conductivity of the first metal member 3 can be increased, and the heat dissipation characteristics can be improved.

By firing the ceramic substrate 1, reaction layers of the inorganic fillers 5 and the active metal powder 16 are formed on the surfaces of the inorganic fillers 5. The metal compound 6 is mainly disposed on at least a part or all of the surface of the inorganic fillers 5 and at least a part of an inner wall defining the through hole 2. The metal compound 6 includes a filler-surface metal compound 6a disposed on the surface of the inorganic fillers 5 and a wall-surface metal compound 6b disposed on at least a part of the inner wall defining the through hole 2. The metal compound 6 is formed by firing the active metal powder 16, and an example of the active metal powder 16 is at least one selected from TiH₂, CeH₂, ZrH₂, and MgH₂. The active metal powder 16 and components of the inorganic fillers 5 and the inner wall defining the through hole 2 are fired, so that the filler-surface metal compound 6a and the wall-surface metal compound 6b are disposed as reaction products.

The filler-surface metal compound 6a is the metal compound 6 and covers at least a part or all of the surfaces of the inorganic fillers 5. When the inorganic fillers 5 are AlN or Si₃N₄, the filler-surface metal compound 6a is formed on the surfaces of the inorganic fillers 5 as TiN by a reaction between the inorganic fillers 5 and TiH₂ of the active metal powder 16 before firing, for example. The filler-surface metal compound 6a is continuously formed with the surface thereof having jagged irregularities, and the surfaces of the inorganic fillers 5 are also formed with jagged irregularities. The inorganic fillers 5 each having the filler-surface metal compound 6a disposed on the surface are dispersed in the first metal 4 that is continuous.

At least a part of the wall-surface metal compound 6b is disposed as the metal compound 6 on the inner wall defining the through hole 2. For example, in a case in which the ceramic substrate 1 is at least one selected from silicon nitride, aluminum nitride, and boron nitride and the active metal powder 16 before firing is, for example, TiH₂ and TiN, a reaction product is generated and the wall-surface metal compound 6b is formed as a compound on the inner wall defining the through hole 2.

The wall-surface metal compound 6b is continuously formed, with the surface thereof having jagged irregularities, on the surface of the inner wall defining the through hole 2, thereby improving the connection strength of the first metal member 3 in the through hole 2. The plurality of active metal powders 16 indicate that the active metal powders are not one particle but a plurality of particles.

The second metal member 8 is a member electrically connected to the light-emitting element 20 together with the first metal member 3. For example, the second metal member 8 is a wiring line, a wiring pad, or the like disposed on the flat surface and/or the bottom surface of the ceramic substrate 1. The second metal member 8 is disposed on the ceramic substrate 1 so as to be in contact with the top of the first metal member 3. The second metal member 8 is formed in a rectangular shape in the plan view, and the second metal member 8 disposed on the flat surface of the ceramic substrate 1 and the second metal member 8 disposed on the bottom surface of the ceramic substrate 1 may have the same size or different sizes.

For example, the same member as the first metal member 3 may be used as the second metal member 8. The material of the second metal member 8 may be, for example, a simple substance such as Au, Ag, Cu, Pt, or Al, an alloy thereof, or a mixture of a mixed powder thereof and a resin binder. The second metal member 8 can have a form of a plate or a foil having a predetermined thickness, a form having an uneven shape in the cross-sectional view or the plan view, or a linear form such as a straight form or a curved form.

Examples of the resin binder that can be suitably used include a thermosetting resin such as an epoxy resin or a silicone resin, and a thermoplastic resin such as an acrylic resin, a urethane resin, or a polyvinyl resin. The second metal member 8 preferably contains a reducing agent such as an organic acid. Thus, the electrical resistance in the connection with the metal member to which the second metal member 8 is connected can be reduced. Note that the second metal member 8 is not particularly limited as long as it is a member generally used as a wiring line and can perform an electrical connection.

Note that the organic binder 7 contained in the first metal paste 3A when the first metal member 3 is the first metal paste 3A before firing is evaporated after firing and does not remain in the first metal paste 3A. The organic binder 7 may be, for example, a solvent and a resin material generally used as a via material.

In the ceramic sintered body substrate 10 having the above configuration, since the first metal member 3 is firmly bonded to the through hole 2 of the ceramic substrate 1 in a state in which volume shrinkage is reduced, reliability is high and an electrical connection with the light-emitting element can be ensured. When the first metal paste 3A is disposed and fired after the through hole 2 is formed in the ceramic substrate 1 having high thermal conductivity, the first metal paste 3A disposed in the through hole 2 does not shrink in volume at the time of firing, and voids are not generated in the through hole 2 and recesses are not easily generated therein. Thus, a connection with the light-emitting element 20 and the like can be stabilized.

Note that the number of through holes 2 in the ceramic substrate 1 may be two or more, for example, four, six, eight or more, and the shape thereof is not limited to an elliptical shape, a rectangular shape or the like, or a circular shape.

The shape of the second metal member 8 may be a square shape, a rectangular shape, a trapezoidal shape, or a shape including a curved portion. Without providing the second metal member 8, the light-emitting element 20 or the like may be connected to a part of the first metal member 3.

Method for Manufacturing Ceramic Sintered Body Substrate

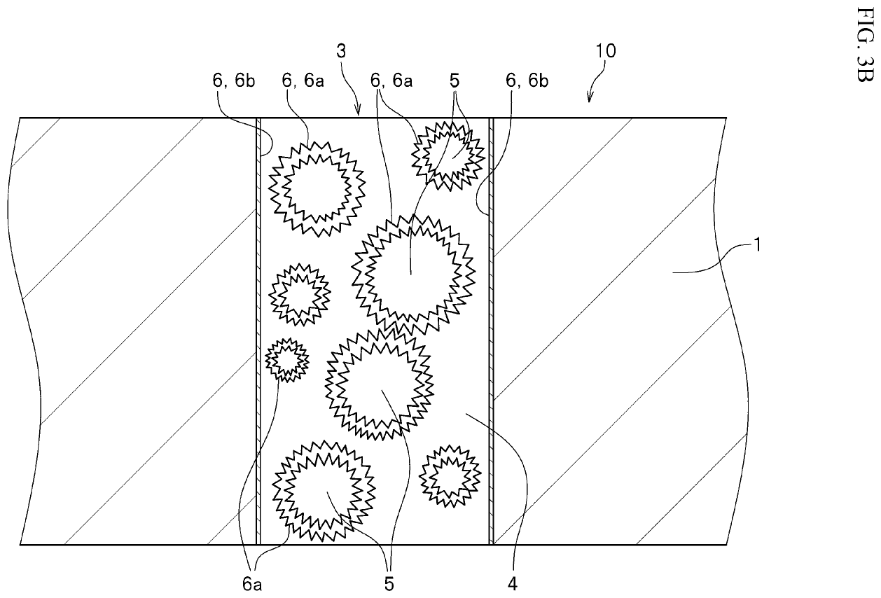

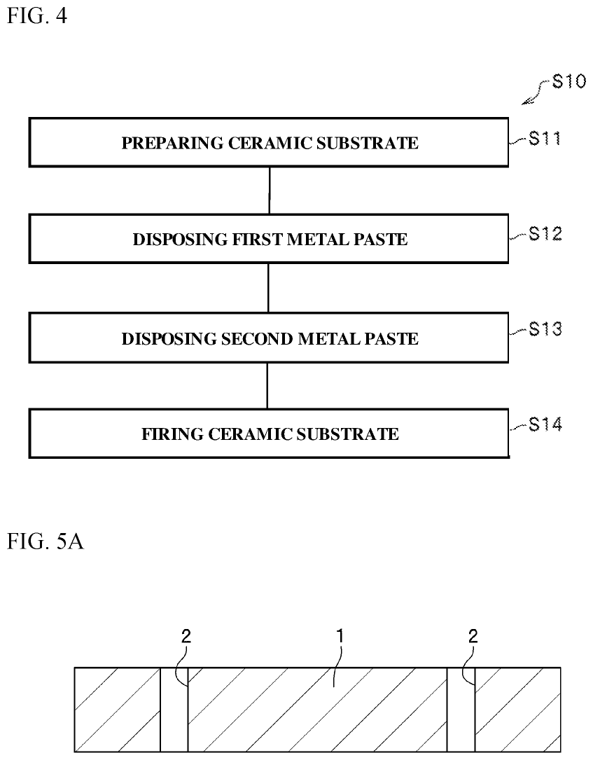

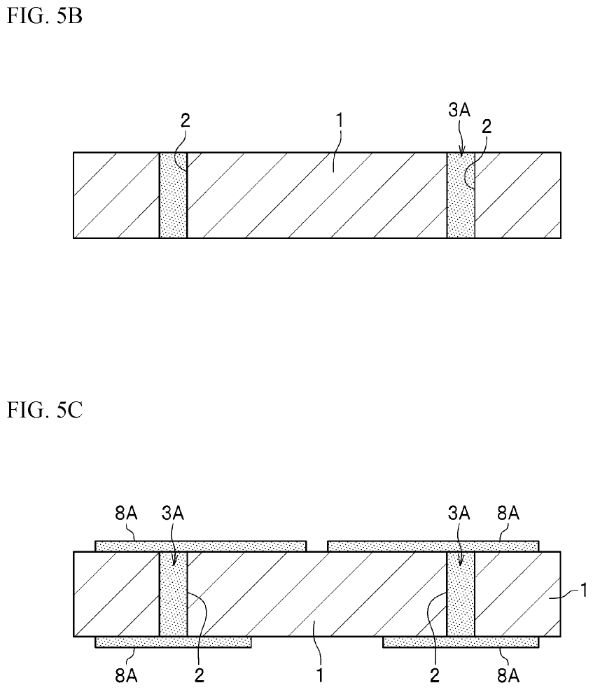

A method for manufacturing the ceramic sintered body substrate according to the embodiment is described below with reference to FIGS. 4 and 5A to 5C. FIG. 4 is a flowchart exemplifying the method for manufacturing the ceramic sintered body substrate according to the embodiment. FIG. 5A is a cross-sectional view schematically illustrating a prepared ceramic substrate in the method for manufacturing the ceramic sintered body substrate according to the embodiment. FIG. 5B is a cross-sectional view schematically illustrating a state in which a through hole is filled with a first metal paste in the method for manufacturing a ceramic sintered body substrate according to the embodiment. FIG. 5C is a cross-sectional view schematically illustrating a state in which second metal pastes are disposed in the method for manufacturing the ceramic sintered body substrate according to the embodiment.

A method S10 for manufacturing the ceramic sintered body substrate includes S12 of disposing the first metal paste on a surface of the ceramic substrate and S14 of firing the ceramic substrate on which the first metal paste is disposed, and in S12 of disposing the first metal paste, the first metal paste contains a plurality of first metal powders, a plurality of active metal powders, and a plurality of inorganic fillers excluding metals. In S14 of firing the ceramic substrate, the firing temperature is a temperature equal to or higher than a melting point of the first metal powders. The surface of the ceramic substrate 1 is at least one of a flat surface, a bottom surface, a lateral surface, and the like of the ceramic substrate, and unless otherwise specified, the same applies to the following description. Note that the method S10 for manufacturing the ceramic sintered body substrate may include S11 of preparing the ceramic substrate before S12 of disposing the first metal paste. The method S10 may include S13 of disposing the second metal pastes between S12 of disposing the first metal paste and S14 of firing the ceramic substrate.

In order to describe a ceramic substrate having a through hole as an example, the method S10 is assumed to include S11 of preparing a ceramic substrate having a through hole, S12 of disposing the first metal paste in the through hole, S13 of disposing the second metal pastes on the surface of the first metal paste and the surface of the ceramic substrate, and S14 of firing the ceramic substrate on which the first metal paste and the second metal pastes are disposed.

Preparing Ceramic Substrate

In S11 of preparing the ceramic substrate (hereinafter, referred to as step S11), for example, a substrate having a flat plate shape and made of at least one material selected from silicon nitride, aluminum nitride, and boron nitride is prepared. In step S11, the prepared ceramic substrate 1 is provided with through holes 2 by laser processing, punching, or the like, the through holes 2 corresponding in number to connecting portions such as element electrodes 24 of the light-emitting element 20 to be described below. When one light-emitting element 20 is disposed on the ceramic substrate 1, for example, the through holes 2 are formed at two positions. Note that the ceramic substrate 1 may be prepared in a state in which the through holes 2 corresponding in number to the element electrodes 24 and corresponding to the size of an area in which a plurality of light-emitting elements 20 are disposed, or may be prepared by being cut into a size for disposing a predetermined number of light-emitting elements 20.

In step S11, the through hole 2 formed in the ceramic substrate 1 has a circular shape when cut horizontally with respect to the ceramic substrate 1, and a diameter of the through hole 2 is preferably in a range from 0.05 mm to 0.5 mm. When the through hole 2 is formed, the through hole 2 has a circular shape as an example, but the shape is not particularly limited.

Disposing First Metal Paste

Step S12 of disposing the first metal paste (hereinafter, referred to as step S12) is to dispose the first metal paste 3A on the surface of the ceramic substrate 1. In step S12, the first metal paste 3A is disposed on the surface of the ceramic substrate 1 by filling the formed through hole 2 with the first metal paste 3A. In step S12, the first metal paste 3A is disposed by filling the through hole 2 with the first metal paste 3A by, for example, screen printing, metal mask printing, or injection using a nozzle so as to have the same surface height as the surface of the ceramic substrate 1. For example, the first metal paste contains a plurality of first metal powders 14, a plurality of inorganic fillers 5, a plurality of active metal powders 16 to be the metal compound 6 on at least a part of the surfaces of the inorganic fillers 5 and at least a part of the inner wall defining the through hole 2, and an organic binder 7. When the total amount of the inorganic fillers 5, the first metal powders 14, and the active metal powders 16 is 100 wt %, the first metal paste 3A contains the inorganic fillers 5 in a range from 1 wt % to 50 wt %, the first metal powders 14 in a range from 40 wt % to 95 wt %, the active metal powders 16 in a range from 1 wt % to 15 wt %, and the organic binder 7 as a solvent in an allowable range of wt %. The content of the inorganic fillers 5 is preferably in a range from 1 wt % to 4.5 wt %, and is more preferably in a range from 1.5 wt % to 4.2 wt %. In step S12, the first metal powders 14 are preferably at least one selected from powders of Ag, Cu, an Ag—Cu alloy, a Cu—Zn alloy, and a Cu—Sn alloy. The active metal powders 16 are preferably at least one selected from powders of Ag, Al, Zn, Sn, and an Ag—Cu alloy. In step S12, the median diameter of the first metal powders 14 is preferably in a range from 1 μm to 50 μm. Moreover, the melting point of the first metal powders 14 is preferably in a range from 700° C. to 1200° C., and is more preferably in a range from 700° C. to 1100° C.

In step S12, the active metal powders 16 are preferably at least one selected from TiH₂, CeH₂, ZrH₂, and MgH₂. When the through hole 2 is filled with the first metal paste 3A in step S12, the first metal paste 3A is preferably disposed on the surface of the ceramic substrate 1 by filling the through hole 2 with the first metal paste from a first surface, which is one surface of the ceramic substrate 1, by using, for example, a squeegee as a tool used for screen printing, and filling the through hole 2 with the first metal paste from a second surface, which is the other surface of the ceramic substrate 1, by using a squeegee in the same manner as that of the first surface. That is, the first metal paste 3A may be disposed on the flat surface and/or the bottom surface of the ceramic substrate 1 continuously from the through hole 2.

Disposing Second Metal Paste

Subsequently, S13 of disposing second metal pastes 8A (hereinafter, referred to as step S13) is performed. In step S13, the second metal pastes 8A are disposed on the ceramic substrate 1 such that at least a part of each of the second metal pastes 8A is in contact with the first metal paste 3A filled in the through hole 2. In step S13, the second metal pastes 8A are each disposed in contact with the entire surface of the first metal paste 3A exposed from the through hole 2 of the ceramic substrate 1. For example, the second metal pastes 8A are disposed in a rectangular shape at a total of four positions including two positions on the first surface of the ceramic substrate 1 and two positions on the second surface of the ceramic substrate 1. Subsequently, the second metal pastes 8A are disposed, as a rectangular wiring line or wiring pad, on the first surface and the second surface of the ceramic substrate 1 through a mask by screen printing, metal mask printing, or the like.

Note that the first metal paste 3A and the second metal paste 8A used in step S12 and step S13 have fluidity and can freely fill the through hole 2 having an arbitrary shape, and can be disposed by being cured after being applied in an arbitrary shape and with an arbitrary thickness.

Preferably, after the first metal paste 3A is disposed and before the ceramic substrate 1 is fired, the first metal paste 3A is further dried and the dried first metal paste 3A is pressurized. The first metal paste 3A may be dried by being placed in an electric furnace having an atmosphere at a temperature higher than room temperature and lower than 100° C., for example. When the ceramic substrate 1 is placed in the electric furnace, drying and pressurization are preferably performed at a time through a mold for pressurization. By drying and pressurizing, volume shrinkage of the first metal paste 3A is less likely to occur at the time of subsequent firing.

Firing Ceramic Substrate

Subsequently, S14 of firing the ceramic substrate (hereinafter, referred to as step S14) is performed. Step S14 is performed using a firing furnace such as an electric furnace at a firing temperature in a range from 700° C. to 1200° C., preferably 700° C. to 1100° C., for example. In step S14, when the firing operation is performed, the firing atmosphere is preferably an Ar atmosphere of 99.9% or more or a vacuum atmosphere of 10⁻⁵ Pa or less.

Through step S14, the ceramic sintered body substrate 10 can be manufactured. As illustrated in FIG. 3B, in the state of the first metal member 3 after the firing of the first metal paste 3A, the inorganic fillers 5 provided on the surfaces thereof with the filler-surface metal compound 6a as the metal compound 6 are disposed in a dispersed state in an Ag—Cu alloy in which the first metal powders 14 are continuous. The wall-surface metal compound 6b as the metal compound 6 is disposed on a part of the inner wall defining the through hole 2 of the ceramic substrate 1. This is because after firing, the active metal powders 16 form a compound on the surfaces of the inorganic fillers 5 as a metal compound and form a metal compound on the inner wall defining the through hole 2 of the ceramic substrate 1.

In this way, after the firing of the first metal paste 3A, a compound obtained by reaction of the active metal powders 16 is formed on at least a part of the surfaces of the inorganic fillers 5, a compound obtained by reaction of the active metal powders 16 is formed on at least a part of the inner wall defining the through hole 2, and the inorganic fillers 5 are dispersed in the first metal member 3. Thus, volume shrinkage of the first metal member 3 is reduced. Consequently, the ceramic sintered body substrate 10 can be stably connected to connection components such as the second metal member 8 and the light-emitting element 20 without generating voids or recesses in the through hole 2, and a highly reliable configuration can be achieved.

Light-Emitting Device

A light-emitting device 100 according to an embodiment is described below with reference to FIG. 6. The light-emitting device 100 is a device in which the light-emitting element 20 is disposed on the ceramic sintered body substrate 10 to emit light. Although the number of light-emitting elements 20 is one in the drawing, the number of light-emitting elements 20 may be more than one. The arrangement thereof is not particularly limited; for example, the light-emitting elements 20 may be arranged in a line.

The light-emitting device 100 includes the ceramic sintered body substrate 10 described above and the light-emitting element 20 electrically connected to the first metal member 3 or the second metal member 8 serving as the wiring line of the ceramic sintered body substrate 10. Note that in the light-emitting device 100, a light reflective member 30 covering the lateral surfaces of the light-emitting element 20 and the upper surface of the ceramic sintered body substrate 10 is disposed as an example. In the ceramic sintered body substrate 10, various patterns of wiring lines can be formed depending on the application. The first metal member 3 includes the plurality of inorganic fillers 5, the first metal 4, and the metal compound 6, and the metal compound 6 is disposed on the surfaces of the plurality of inorganic fillers 5 and at least a part of the surface of the inner wall defining the through hole 2 of the ceramic substrate 1.

Light-Emitting Element

The light-emitting element 20 includes a pair of element electrodes 24, a light-transmissive member 23 disposed on a light extraction surface side of the light-emitting element 20, an element substrate 22, and a semiconductor layered body 21. The light-emitting element 20 includes, for example, the semiconductor layered body 21 on the element substrate 22, and in the present embodiment, the light-transmissive member 23 is disposed on a side of a flat surface serving as a light extraction surface of the element substrate 22, the semiconductor layered body 21 is provided on a bottom surface side of the element substrate 22, and the pair of element electrodes 24 is provided on the semiconductor layered body 21 side. For the semiconductor layered body 21, any composition can be used depending on a desired emission wavelength, and for example, a nitride semiconductor (In_{X}Al_{Y}Ga_{1-X-Y}N, 0≤X, 0≤Y, X+Y≤1) or GaP, which can emit blue or green light, or GaAlAs or AlInGaP, which can emit red light, can be used. The size and shape of the light-emitting element 20 can be appropriately selected according to the purpose of use.

For example, a sapphire substrate or a silicon substrate is used as the element substrate 22.

For example, the light-transmissive member 23 is made of a light-transmissive resin material, and an epoxy resin, a silicone resin, a resin in which an epoxy resin and a silicone resin are mixed, or the like can be used. The light-transmissive member 23 may contain a phosphor, and for example, when the light-transmissive member 23 contains a phosphor that absorbs blue light from the light-emitting element 20 and emits yellow light, white light can be emitted from the light-emitting element 20. The light-transmissive member 23 may further contain a plurality of types of phosphors, and for example, when the light-transmissive member 23 contains a phosphor that absorbs blue light from the semiconductor layered body 21 and emits green light and a phosphor that emits red light, white light can be emitted from the light-emitting element 20.

Examples of such a phosphor that can be used include an yttrium aluminum garnet-based phosphor (Y₃(Al,Ga)₅O₁₂:Ce, for example), a lutetium aluminum garnet-based phosphor (Lu₃(Al,Ga)₅O₁₂:Ce, for example), a terbium aluminum garnet-based phosphor (Tb₃(Al,Ga)₅O₁₂:Ce, for example), a β-SiAlON phosphor ((Si,Al)₃(O,N)₄:Eu, for example), an α-SiAlON phosphor (M_{z}(Si,Al)₁₂(O,N)₁₆ (where 0<z≤2, and M is Li, Mg, Ca, Y, or a lanthanoid element excluding La and Ce)), a nitride phosphor such as a CASN-based phosphor (CaAlSiN₃:Eu, for example) or an SCASN-based phosphor ((Sr,Ca)AlSiN₃:Eu, for example), a fluoride phosphor such as a KSF-based phosphor (K₂SiF₆:Mn, for example), a KSAF-based phosphor (K₂(Si,Al)F₆:Mn), or an MGF-based phosphor (3.5MgO·0.5MgF₂·GeO₂:Mn, for example), and a quantum dot phosphor such as perovskite or chalcopyrite.

The element electrodes 24 are each connected to a corresponding one of the second metal members 8 of the ceramic sintered body substrate 10 via a corresponding one of bonding members 11 by metal bumps 12. One of the element electrodes 24 is a p-electrode 24a, and the p-electrode 24a is disposed at a distance from the other element electrode 24, that is, an n-electrode 24b so as not to be electrically short-circuited therewith. For example, the element electrodes 24 are configured such that one p-electrode 24a and one n-electrode 24b are disposed at respective positions, but may be configured such that one of the p-electrode 24a and the n-electrode 24b is disposed at two positions and the other is disposed at one position.

The metal bumps 12 electrically connect the element electrode 24 and the second metal member 8. The metal bumps 12 may be disposed either on the element electrode 24 side or on the second metal member 8 side. The shape, size, and number of the metal bumps 12 can be appropriately set as long as they can be disposed within the range of the element electrodes 24. The size of the metal bump 12 can be appropriately adjusted depending on the size of the semiconductor layered body, the required light emission output of the light-emitting element, and the like, and for example, the metal bump 12 has a diameter of about several tens of μm to several hundreds of μm.

The metal bump 12 can be made of, for example, Au, Ag, Cu, Al, Sn, Pt, Zn, Ni, or an alloy thereof, and can be formed of, for example, a stud bump known in the art. The stud bump can be formed by a stud bump bonder, a wire bonding apparatus, or the like. The metal bump 12 may also be formed by a method known in the art such as electroplating, electroless plating, vapor deposition, or sputtering.

For example, the metal bumps 12 are bonded via the bonding member 11. Examples of the bonding member 11 used herein include solders such as tin-bismuth based solders, tin-copper based solders, tin-silver based solders, and gold-tin based solders, eutectic alloys such as alloys containing Au and Sn as main components, alloys containing Au and Si as main components, and alloys containing Au and Ge as main components, paste materials of silver, gold, palladium, and the like, anisotropic conductive materials such as ACP and ACF, brazing filler metals made from low melting point metals, conductive adhesives and conductive composite adhesives of a combination of any of these. The bonding member 11 may be disposed not only on the surface of the second metal member 8 on the first surface side of the ceramic substrate 1 but also on the surface of the second metal member 8 on the second surface side of the ceramic substrate 1.

Light Reflective Member

The light reflective member 30 is a member having light reflectivity. The light reflective member 30 covers the first surface of the ceramic sintered body substrate 10 and the lateral surfaces of the light-emitting element 20. The light reflective member 30 is disposed exposing the light extraction surface of the light-emitting element 20 and is flush with the light-emitting element 20. For example, the light reflective member 30 is also disposed between the lower surface of the light-emitting element 20 and the first surface of the ceramic sintered body substrate 10.

The light reflective member 30 preferably has a high reflectance in order to effectively use light from the light-emitting element 20. The light reflective member 30 is preferably white. The reflectance of the light reflective member 30 is, for example, preferably 90% or more, and more preferably 94% or more at the wavelength of the light emitted from the light-emitting element 20.

Examples of the resin for the light reflective member 30 that can be used includes a thermoplastic resin such as an acrylic resin, a polycarbonate resin, a cyclic polyolefin resin, a polyethylene terephthalate resin, a polyethylene naphthalate resin, or a polyester resin, and a thermosetting resin such as an epoxy resin or a silicone resin. Examples of a light diffusing material that can be used include known materials such as titanium oxide, silica, alumina, zinc oxide, and glass.

Since the light-emitting device 100 having the configuration described above includes the first metal member 3 in the ceramic sintered body substrate 10, volume shrinkage is reduced as described above. By adding a predetermined amount of the inorganic fillers 5, a linear expansion coefficient can also be reduced. Consequently, the light-emitting device 100 can be stably connected to connection components such as the second metal member 8 and the light-emitting element 20 without generating voids or recesses in the through hole 2, and can have a highly reliable configuration.

Although the light-emitting device 100 uses one light-emitting element 20 as one unit to control brightness and turning on/off, the number of light-emitting elements 20 included in one unit may be either one or more than one. For example, four light-emitting elements 20 arranged in one row and four columns or two rows and two columns, or nine light-emitting elements 20 arranged in three rows and three columns can be used as one unit, and the number of light-emitting elements 20 is not limited.

Method for Manufacturing Light-Emitting Device

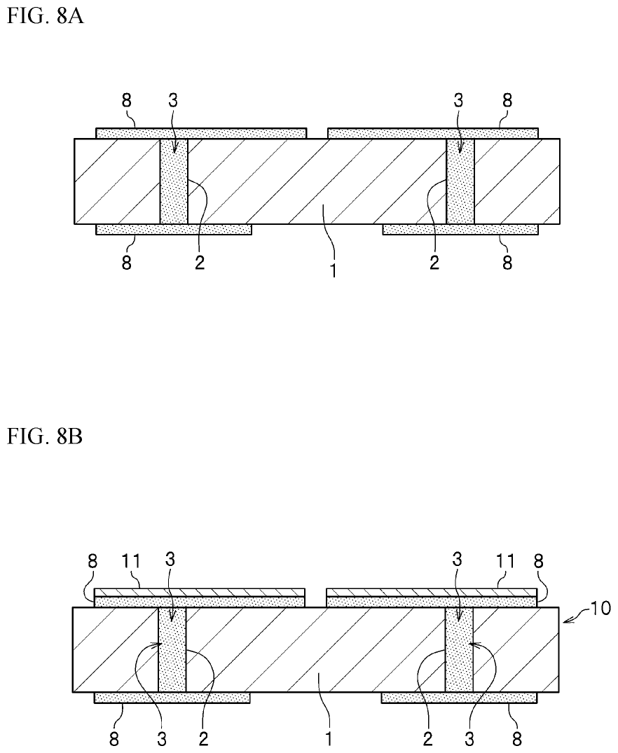

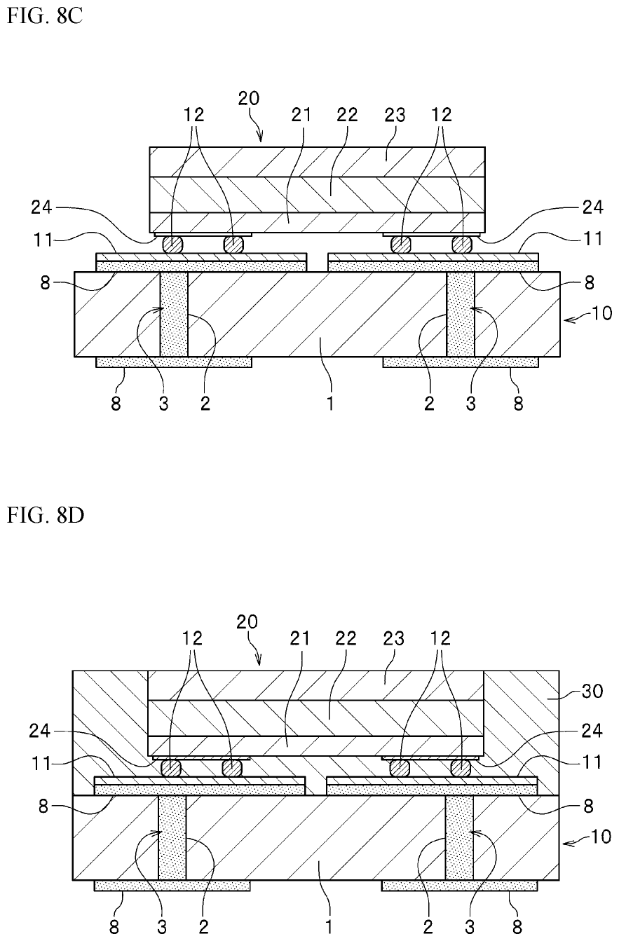

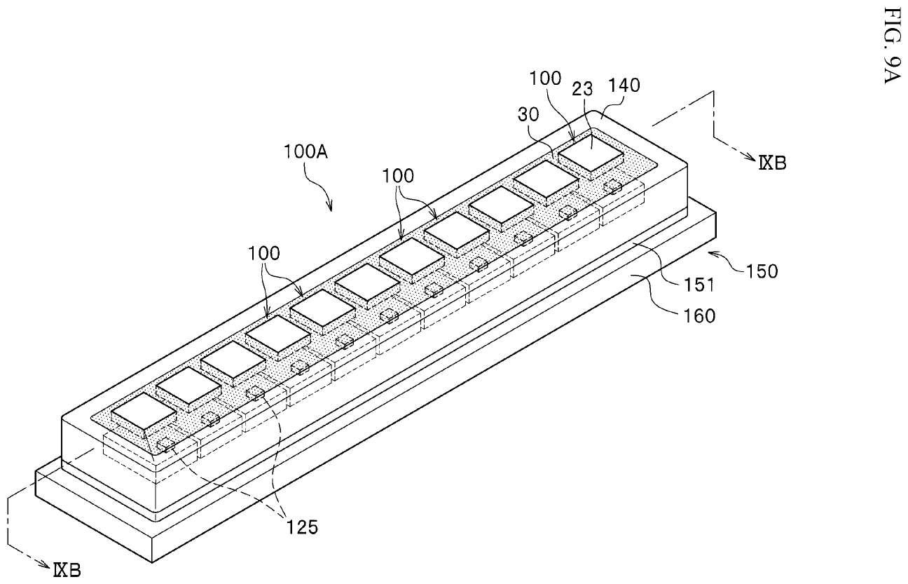

A method for manufacturing the light-emitting device according to the embodiment is described below with reference to FIGS. 7 and 8A to 8D. FIG. 7 is a flowchart exemplifying the method for manufacturing the light-emitting device according to the embodiment. FIG. 8A is a cross-sectional view schematically illustrating a prepared ceramic sintered body substrate in the method for manufacturing the light-emitting device according to the embodiment. FIG. 8B is a cross-sectional view schematically illustrating a state in which a bonding member is disposed on the ceramic sintered body substrate. FIG. 8C is a cross-sectional view schematically illustrating a state in which a light-emitting element is disposed in the method for manufacturing the light-emitting device according to the embodiment. FIG. 8D is a cross-sectional view schematically illustrating a state in which a light reflective member is disposed in the method for manufacturing the light-emitting device according to the embodiment.

A method S20 for manufacturing the light-emitting device includes S21 of preparing the ceramic sintered body substrate manufactured by the method S10 for manufacturing the ceramic sintered body substrate described above, and S22 of disposing a light-emitting element on the ceramic sintered body substrate. S21 of preparing the ceramic sintered body substrate includes disposing a first metal paste on the surface of a ceramic substrate and firing the ceramic substrate on which the first metal paste is disposed. In the disposing of the first metal paste, the first metal paste contains a plurality of first metal powders, a plurality of active metal powders, and a plurality of inorganic fillers excluding metals. The disposing of the light-emitting element includes directly or indirectly electrically connecting a first metal member formed by firing the first metal paste to the light-emitting element. Note that in S22 of disposing the light-emitting element, the element electrodes 24 may be directly or indirectly connected to the second metal pastes 8A in contact with at least parts of the first metal pastes 3A. In the method S20 for manufacturing the light-emitting device, S23 of disposing a light reflective member is performed after S22 of disposing the light-emitting element.

Preparing Ceramic Sintered Body Substrate

S21 of preparing the ceramic sintered body substrate (hereinafter, referred to as step S21) is to prepare the ceramic sintered body substrate 10 manufactured by the method S10 for manufacturing the ceramic sintered body substrate described above. The second metal pastes 8A connected to the corresponding first metal pastes 3A filled and disposed in the corresponding through holes 2 are disposed at respective four positions on the first surface and the second surface of the ceramic sintered body substrate 10. Note that the shape, size, and interval of the second metal pastes 8A can be adjusted in accordance with the element electrodes 24 of the light-emitting element 20. Note that the ceramic sintered body substrate 10 may include a plurality of regions in which the light-emitting elements 20 are disposed, and may have a size for singulation to separate the light-emitting devices 100 after the light reflective member 30 to be described below is disposed, or the ceramic sintered body substrate 10 may have a size for each light-emitting device 100.

Disposing Light-Emitting Element

S22 of disposing the light-emitting element (hereinafter, referred to as step S22) is to dispose the light-emitting element 20 on the ceramic sintered body substrate 10. In step S22, the element electrodes 24 of the light-emitting element 20 are connected to the corresponding bonding members 11 disposed on the corresponding second metal pastes 8A by using the metal bumps 12. Note that the light-emitting element 20 is disposed in a state in which the light-transmissive member 23 is connected to the element substrate 22 in advance. When the light-transmissive member 23 is bonded to the element substrate 22, a light-transmissive bonding material is used.

Disposing Light Reflective Member

S23 of disposing the light reflective member (hereinafter, referred to as step S23) is to dispose the light reflective member 30 covering the first surface which is the flat surface of the ceramic sintered body substrate 10 and covering the lateral surfaces of the light-emitting element 20. In step S23, the light reflective member 30 is disposed on the ceramic sintered body substrate 10 so as to surround the light-emitting element 20 and expose the upper surface of the light-transmissive member 23 serving as the light extraction surface of the light-emitting element 20. The light reflective member 30 is disposed so as to have a rectangular shape in a plan view.

Note that in the method S20 for manufacturing the light-emitting device, a singulation operation is performed as necessary after the operation of step S23 is completed. In the light-emitting device 100, one unit of the light-emitting device 100 is set in advance by the number of light-emitting elements 20 used. Therefore, when a plurality of light-emitting devices 100 are collectively manufactured, a singulation operation is performed. When the singulation operation is performed, a plurality of light-emitting devices 100 are produced by cutting in a lattice pattern. For example, a rotating blade having a disk shape, an ultrasonic cutter, laser light irradiation, a blade, or the like can be used as the cutting method.

According to the method S20 for manufacturing the light-emitting device having the configuration described above, a stable connection to connection components such as the second metal member 8 and the light-emitting element 20 can be performed since voids or recesses are not generated in the through hole 2 by the method S10 for manufacturing the ceramic sintered body substrate, and a highly reliable configuration can be obtained.

### Application Example

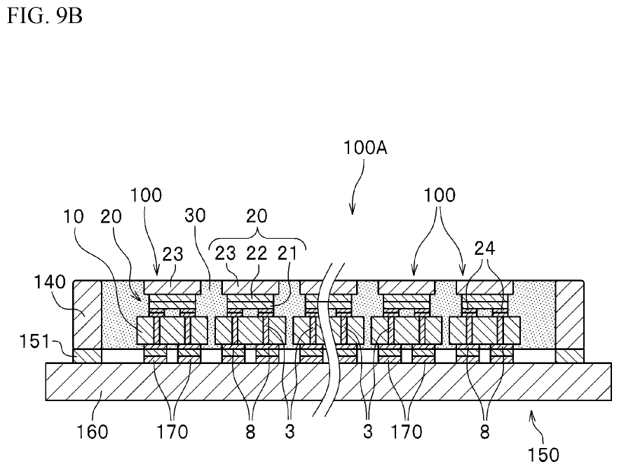

As illustrated in FIGS. 9A and 9B, a light-emitting module 100A including a plurality of (eleven in the drawing) light-emitting devices 100 in a line may be used, or eleven light-emitting devices 100 may be mounted on one ceramic sintered body substrate 10. A configuration of the light-emitting module 100A is described below. FIG. 9A is a perspective view illustrating an application example of a light-emitting device. FIG. 9B is a cross-sectional view illustrating a cross-section with a part of FIG. 9A omitted.

The light-emitting module 100A includes eleven light-emitting devices 100 in a line, includes a frame body 140 outside the light reflective member 30, and includes a module substrate 150 connected to the second metal members 8 below the ceramic sintered body substrates 10.

The frame body 140 is a member for surrounding the light reflective member 30 that covers the plurality of light-emitting devices 100. The frame body 140 is formed in a rectangular annular shape that is, for example, rectangular in a plan view, and surrounds the periphery of the light reflective member 30. The frame body 140 can be formed using a member having a frame shape and made of a metal, an alloy, or a ceramic member. Examples of the metal include Fe, Cu, Ni, Al, Ag, Au, Pt, Ti, W, and Pd. Examples of the alloy include an alloy containing at least one of Fe, Cu, Ni, Al, Ag, Au, Pt, Ti, W, and Pd. A resin material may be used as the frame body 140. In this case, the metal, the alloy, or the ceramic member may be embedded in the frame body 140 made of the resin material, or a part of the frame body 140 may be made of a resin material and another part thereof may be made of a metal, an alloy, or a ceramic member.

The module substrate 150 is a member on which the light-emitting device 100 is mounted, and electrically connects the light-emitting device 100 to the outside. The module substrate 150 is formed in a substantially rectangular shape in the plan view, for example. The module substrate 150 includes a substrate portion 160 and wiring board portions 170.

As a material of the substrate portion 160, for example, an insulating material is preferably used, and a material that does not easily transmit light emitted from the light-emitting element 20, external light, and the like is preferably used. Examples of the material of the substrate portion 160 that can be used include a ceramic such as alumina, aluminum nitride, or mullite, a thermoplastic resin such as polyamide, polyphthalamide, polyphenylene sulfide, or a liquid crystal polymer, and a resin such as an epoxy resin, a silicone resin, a modified epoxy resin, a urethane resin, or a phenol resin. In particular, a ceramic having excellent heat dissipation is preferably used.

The wiring board portions 170 are formed on the substrate portion 160 at a position facing the second metal members 8 below the light-emitting devices 100. Examples of a material of the wiring board portions 170 include those exemplified as the materials used for the first metal member 3, the second metal member 8, and the like.

Note that the module substrate 150 is bonded to the frame body 140 via a conductive adhesive 151, and is disposed such that the second metal members 8 and the wiring board portions 170 are bonded to each other. For example, a eutectic solder, a conductive paste, or a bump may be used for the conductive adhesive 151. In the light-emitting device 100, a protective element 125 is disposed on each ceramic sintered body substrate 10 in parallel with each light-emitting element 20.

Since the light-emitting module 100A is configured as described above, the light-emitting module 100A is driven as follows. That is, in the light-emitting module 100A, a current is supplied from an external power supply to the light-emitting elements 20 via the wiring board portions 170, the second metal members 8, the first metal members 3, and the element electrodes 24, so that the light-emitting elements 20 emit light. Of the light emitted from the light-emitting element 20, light traveling upward is extracted to the outside above the light-emitting device 100 via the light-transmissive member 23. Light traveling downward is reflected by the ceramic sintered body substrate 10 and is extracted to the outside of the light-emitting device 100 via the light-transmissive member 23. Light traveling between the light-emitting element 20 and the frame body 140 is reflected by the light reflective member 30 and the frame body 140 and extracted to the outside of the light-emitting device 100 via the light-transmissive member 23. Light traveling between the light-emitting elements 20 is reflected by the light reflective member 30 and extracted to the outside of the light-emitting device 100 via the light-transmissive member 23. At this time, if a space between the light-transmissive members 23 is narrow (for example, equal to or less than 0.2 mm), for example, when the light-emitting module 100A is employed for a light source of a vehicle headlight, a configuration of an optical system can be simplified and reduced in size.

Note that when the light-emitting module 100A is manufactured, the light-emitting devices 100 are arranged on a sheet member, the frame body 140 is disposed around the light-emitting devices 100, and a space surrounded by the frame body 140 and the sheet member is filled with the light reflective member 30 in this state, whereby the light reflective member 30 is disposed. Subsequently, by disposing the light-emitting devices 100 supported by the frame body 140 and the light reflective member 30 on the module substrate 150 on which the wiring board portions 170 and the conductive adhesive 151 are disposed and electrically connecting the second metal members 8 and the wiring board portions 170, the light-emitting module 100A is manufactured.

### EXAMPLES

Next, the ceramic sintered body substrate according to the embodiment of the present disclosure will be described regarding Examples as shown below. Note that the invention is not limited to the following Examples.

In the Examples disclosed below, Example 1 and Example 2 were manufactured, and Comparative Example 1 was manufactured, and the thermal conductivities of these were measured and compared as a measurement result 1. In addition, in the Examples disclosed, Example 3, Example 4, and Example 5 were manufactured, and Comparative Example 2 was manufactured, and changes in thickness of the respective first metal pastes after firing were compared as a measurement result 2.

Ceramic substrates used in the following Examples and Comparative Examples had a thickness of 250 μm and were made of silicon nitride.

In Example 1, Example 2, and Comparative Example 1, bulk bodies having a size of about 10 mm×10 mm×5 mm were formed in order to measure the thermal conductivities.

In Example 3 to Example 5, and Comparative Example 2, a mask having a predetermined through hole was disposed on both surfaces of the ceramic substrate, and irradiated with a laser to form a through hole. The through hole in each ceramic substrate had a circular truncated cone shape with a diameter of 230 μm on the upper surface of the ceramic substrate and a diameter of 130 μm on the lower surface thereof. A first metal paste was disposed in the through hole provided in the mask and the through hole provided in the ceramic substrate. Thereafter, the first metal paste was dried, the mask was peeled off, and the ceramic substrate was fired.

In Example 6 to Example 10, and Comparative Example 3, with no mask applied to the ceramic substrate, the ceramic substrate was irradiated with a laser to form a through hole. The through hole in each ceramic substrate had a circular truncated cone shape with a diameter of 230 μm on the upper surface of the ceramic substrate and a diameter of 130 μm on the lower surface thereof. A first metal paste was disposed in the through hole provided in the ceramic substrate. Thereafter, the first metal paste was dried and the ceramic substrate was fired.

### Example 1

The first metal powder contained 50 wt % of a eutectic powder of silver and copper (the eutectic composition was 72 wt % of silver and 28 wt % of copper) and 50 wt % of a silver powder. For a first metal paste according to Example 1, based on 100 parts by mass of this first metal powder, 5 parts by mass of an active metal powder (titanium hydride (TiH₂)), 0.5 parts by mass of an organic solvent (polyvinyl acetal resin), and 0.5 parts by mass of a dispersant (lauric acid) were used, and 2 parts by mass of an inorganic filler (AlN) was used. The firing temperature was 830° C. When the total amount of the inorganic filler, the first metal powder, and the active metal powder was 100 wt %, the content of the inorganic filler was 1.87 wt %.

### Example 2

Example 2 was the same as Example 1 except that the amount of the inorganic filler was different. In Example 2, 5 parts by mass of the inorganic filler (AlN) was used. When the total amount of the inorganic filler, the first metal powder, and the active metal powder was 100 wt %, the content of the inorganic filler was 4.55 wt %.

### Comparative Example 1

Comparative Example 1 was the same as Example 1 except that no inorganic filler was used.

Measurement Result 1

The thermal conductivities of Examples 1, 2, and Comparative Example 1 were measured. While the thermal conductivity of Comparative Example 1 was 209.2 W/m·K, the thermal conductivity of Example 1 was 202.9 W/m·K and the thermal conductivity of Example 2 was 176.5 W/m·K. From this point, Example 1 had a thermal conductivity lower than that of Comparative Example 1. In addition, Example 2 had a thermal conductivity further lower than that of Comparative Example 1 and lower than that of Example 1. In addition, the fact that Example 1 and Example 2 contained the inorganic filler affected the difference in thermal conductivity from Comparative Example 1, and it is more preferable that an inorganic filler is contained in a predetermined range. That is, although Example 1 and Example 2 preferably have high thermal conductivities, the thermal conductivity, which is decreased by the inorganic filler being contained, is maintained at a certain value or more in accordance with a relation with the amount of change in thickness described below.

Thermal Conductivity

The thermal conductivities of Examples and Comparative Examples were estimated. The thermal conductivity can be obtained as a product of specific heat, density, and thermal diffusivity. Specifically, the thermal conductivity is expressed by the following equation:

Thermal conductivity [W/m·K]=thermal diffusivity [m²/sec]×specific heat [J/K·kg]×density [kg/m³].

The specific heat was obtained for each Example and each Comparative Example by weighting a documented value of the specific heat of each material with a mixed mass ratio. The density was measured by the Archimedes' method. The thermal diffusivity was obtained by the flash method using a measurement device (model number: LFA-447) manufactured by NETZSCH Japan K.K. and by using a xenon lamp. The measurement temperature was 25° C., and the thickness of samples at the time of measurement was 2 mm. The “thermal conductivities” of Example 1, Example 2, and Comparative Example 1 were values estimated from these documented values and measured values.

### Example 3

The first metal powder contained 100 wt % of a eutectic powder of silver and copper (the eutectic composition was 72 wt % of silver and 28 wt % of copper). For a first metal paste according to Example 3, based on 100 parts by mass of this first metal powder, 5 parts by mass of an active metal powder (titanium hydride (TiH₂)), 0.5 parts by mass of an organic solvent (polyvinyl acetal resin), and 0.5 parts by mass of a dispersant (lauric acid) were used, and 1 part by mass of an inorganic filler (AlN) was used. The firing temperature was 830° C. When the total amount of the inorganic filler, the first metal powder, and the active metal powder was 100 wt %, the content of the inorganic filler was 0.94 wt %.

### Example 4

Example 4 was the same as Example 3 except that the amount of the inorganic filler was different. In Example 4, 2 parts by mass of the inorganic filler (AlN) was used. When the total amount of the inorganic filler, the first metal powder, and the active metal powder was 100 wt %, the content of the inorganic filler was 1.87 wt %.

### Example 5

Example 5 was the same as Example 3 except that the amount of the inorganic filler was different. In Example 5, 10 parts by mass of the inorganic filler (AlN) was used. When the total amount of the inorganic filler, the first metal powder, and the active metal powder was 100 wt %, the content of the inorganic filler was 8.70 wt %.

### Comparative Example 2

Comparative Example 2 was the same as Example 3 except that no inorganic filler was used.

Measurement Result 2

Amounts of change in thickness were measured for the first metal paste and the first metal member obtained by firing the first metal paste in Example 3 to Example 5 and Comparative Example 2. While the thickness was changed by 62% in Comparative Example 2, it was confirmed that the amount of change became smaller as the amount of the inorganic filler was increased such that the amount of change was 52% in Example 3, 26% in Example 4, and 22% in Example 5. That is, it can be seen that the fact that Example 3 to Example 5 contained the inorganic filler appeared as differences in amount of change from Comparative Example 2. Then, it can be seen that it is more preferable that the inorganic filler be contained in a predetermined range.

Method for Measuring Shrinkage Rate

In addition, shrinkage rates were calculated in the manner described below, and Examples and Comparative Examples were compared as described below. In Example 3 to Example 5 and Comparative Example 2, through holes of masks provided on both surfaces of a ceramic substrate were filled with a metal paste while an excess was scraped off, and in Example 6 to Example 10 and Comparative Example 3, through holes of a ceramic substrate were filled with a metal paste while an excess was scraped off. After a solvent and a binder were dried, the substrate was observed from lateral sides of the substrate by using an X-ray non-destructive inspection apparatus. The area of the perspective view of the via filler seen in the observation was used as an initial value (S₀). The area of the perspective view (S₁) of the via filler seen after the substrate was fired by using the X-ray non-destructive inspection apparatus in the same manner as described above was subtracted from the initial value, and a proportion of the value thus obtained to the initial value was obtained as a shrinkage rate.

Shrinkage rate=(S₁−S₀)/S₀

As shown in the above-described measurement result 1 and measurement result 2, from the results of the thermal conductivities and the amounts of change in thickness, in order to achieve a high thermal conductivity and a small amount of change in thickness to satisfy both conditions, the amount of the inorganic filler is preferably 1 wt % or more and 4.5 wt % or less, and further preferably 1.5 wt % or more and 4.2 wt % or less.

### Example 6

The first metal powder contained 50 wt % of a eutectic powder of silver and copper (the eutectic composition was 72 wt % of silver and 28 wt % of copper) and 50 wt % of silver powder. For a first metal paste according to Example 6, based on 100 parts by mass of this first metal powder, 5 parts by mass of an active metal powder (titanium hydride (TiH₂)), 0.5 parts by mass of an organic solvent (polyvinyl acetal resin), and 0.5 parts by mass of a dispersant (lauric acid) were used, and 1 part by mass of an inorganic filler (AlN) was used. The firing temperature was 830° C. When the total amount of the inorganic filler, the first metal powder, and the active metal powder was 100 wt %, the content of the inorganic filler was 0.94 wt %. In each of Example 6 to Example 10, two samples having the same configuration were produced under the same conditions, and Example 6 to Example 10 were compared based on shrinkage rates of average values of these two samples. The shrinkage rate was an average value with 2 as a so-called n number.

### Example 7

Example 7 was the same as Example 6 except that the amount of the inorganic filler was different. In Example 7, 2 parts by mass of the inorganic filler (AlN) was used. When the total amount of the inorganic filler, the first metal powder, and the active metal powder was 100 wt %, the content of the inorganic filler was 1.87 wt %.

### Example 8

Example 8 was the same as Example 6 except that the amount of the inorganic filler was different. In Example 8, 5 parts by mass of the inorganic filler (AlN) was used. When the total amount of the inorganic filler, the first metal powder, and the active metal powder was 100 wt %, the content of the inorganic filler was 4.55 wt %.

### Example 9

Example 9 was the same as Example 6 except that the amount of the inorganic filler was different. In Example 9, 10 parts by mass of the inorganic filler (AlN) was used. When the total amount of the inorganic filler, the first metal powder, and the active metal powder was 100 wt %, the content of the inorganic filler was 8.70 wt %.

### Example 10

Example 10 was the same as Example 6 except that the amount of the inorganic filler was different. In Example 10, 20 parts by mass of the inorganic filler (AlN) was used. When the total amount of the inorganic filler, the first metal powder, and the active metal powder was 100 wt %, the content of the inorganic filler was 16.0 wt %.

### Comparative Example 3

Comparative Example 3 was the same as Example 6 except that no inorganic filler was used.

In Example 6 to Example 10 and Comparative Example 3, the thickness of the first metal member after firing was measured relative to the thickness 250 μm of first metal pastes before firing. Both front surface and back surface of the first metal members were dented, and the total amount of reduction in the front surface and the back surface of each first metal member is shown. While the amount of reduction of the first metal member was 27.9 μm in Comparative Example 3, the amount of reduction of the first metal member was 26.8 μm in Example 6, 16.0 μm in Example 7, 18.9 μm in Example 8, 20.9 μm in Example 9, and 9.1 μm in Example 10. From this, it was revealed that the larger the amount of the inorganic filler was, the smaller the amount of reduction in the thickness of the first metal member was.

Note that since in Example 3 to Example 5, the masks were provided on both surfaces of the ceramic substrate, the thickness of the first metal paste was larger by the thicknesses of the masks on both surfaces than those in Example 6 to Example 10. In addition, in Example 3 to Example 5, since firing was conducted after the masks were peeled off, a portion in which the first metal paste was expanded on the ceramic substrate was also observed. Moreover, while Example 6 to Example 10 used 100 wt % of the eutectic powder of silver and copper, which is melted at the firing temperature, Example 3 to Example 5 used only 50 wt % of the eutectic powder of silver and copper, which is melted at the firing temperature. For this reason, Example 3 to Example 5 had larger amounts of reduction of the first metal member than those in Examples 6 to 10. In this way, it can be seen that in a ceramic sintered body substrate, when a first metal paste having predetermined conditions contains a first metal powder, an active metal powder, and an inorganic filler except for metals, the amount of reduction of a first metal member can be reduced.

Note that in the above-described Examples, the organic solvent was evaporated after the firing, and since the amount of the dispersant was very small, there was a case where it became difficult to confirm the presence of the dispersant after the firing.

A light-emitting device according to the embodiments of the present disclosure can be utilized for a variable light distribution type headlamp. In addition, the light-emitting devices according to the embodiments of the present disclosure can be utilized for the light source for a backlight of a liquid crystal display, various types of lighting fixtures, a large display, various types of display devices for advertisements, destination information, and the like, and further, a digital video camera, image reading devices in a facsimile, a copy machine, a scanner, and the like, and a projector device, for example.

1. A method for manufacturing a ceramic sintered body substrate, comprising:
disposing a first metal paste on a surface of a ceramic substrate; and
firing the ceramic substrate on which the first metal paste is disposed, wherein
in the disposing the first metal paste, the first metal paste contains a plurality of first metal powders, a plurality of active metal powders, and a plurality of inorganic fillers excluding metals, and
in the firing the ceramic substrate, a firing temperature is equal to or higher than a melting point of the first metal powder.

2. The method for manufacturing a ceramic sintered body substrate, according to claim 1, further comprising:
preparing the ceramic substrate provided with a through hole before disposing the first metal paste; and
disposing the first metal paste in the through hole.

3. The method for manufacturing a ceramic sintered body substrate, according to claim 1, further comprising, after disposing the first metal paste and before firing the ceramic substrate, drying the first metal paste and pressurizing the first metal paste having been dried.

4. The method for manufacturing a ceramic sintered body substrate, according to claim 1, wherein, in the disposing the first metal paste, when a total amount of the inorganic fillers, the first metal powders, and the active metal powders is 100 wt %, the content of the inorganic fillers is in a range from 1 wt % to 50 wt %, the content of the first metal powders is in a range from 40 wt % to 95 wt %, and the content of the active metal powders is in a range from 0.5 wt % to 15 wt %.

5. The method for manufacturing a ceramic sintered body substrate, according to claim 1, wherein, in the disposing the first metal paste, a melting point of the first metal powder is in a range from 700° C. to 1200° C.

6. The method for manufacturing a ceramic sintered body substrate, according to claim 1, wherein, in the firing the ceramic substrate, the firing temperature is in a range from 700° C. to 1000° C.

7. The method for manufacturing a ceramic sintered body substrate, according to claim 1, wherein, in the firing the ceramic substrate, a reaction layer of the inorganic filler and the active metal powder is formed on a surface of the inorganic filler.

8. The method for manufacturing a ceramic sintered body substrate, according to claim 2, wherein the first metal paste is disposed on a flat surface and/or a bottom surface of the ceramic substrate continuously from the through hole.

9. The method for manufacturing a ceramic sintered body substrate, according to claim 1, wherein after filling with the first metal paste and before firing the ceramic substrate, a second metal paste is disposed on the ceramic substrate such that at least part of the second metal paste is in contact with the first metal paste.

10. A method for manufacturing a light-emitting device, comprising:
preparing a ceramic sintered body substrate manufactured by the method for manufacturing a ceramic sintered body substrate, according to claim 1; and
disposing a light-emitting element on the ceramic sintered body substrate, wherein
in the preparing the ceramic sintered body substrate, the first metal paste becomes a first metal member by firing, and
in the disposing the light-emitting element, the first metal member is directly or indirectly electrically connected to the light-emitting element.

11. A method for manufacturing a light-emitting device, comprising:
preparing a ceramic sintered body substrate manufactured by the method for manufacturing a ceramic sintered body substrate, according to claim 9; and
disposing a light-emitting element on the ceramic sintered body substrate, wherein
in the preparing the ceramic sintered body substrate, the first metal paste becomes a first metal member by firing and the second metal paste becomes a second metal member by the firing, and
in the disposing the light-emitting element, the first metal member or the second metal member is directly or indirectly electrically connected to the light-emitting element.

12. A ceramic sintered body substrate comprising:
a ceramic substrate; and
a first metal member disposed on a surface of the ceramic substrate, wherein
the first metal member contains a plurality of inorganic fillers, a first metal, and a metal compound, and
the metal compound is disposed on at least a part of surfaces of the plurality of inorganic fillers and at least a part of a surface of the ceramic substrate.

13. The ceramic sintered body substrate according to claim 12, wherein
the ceramic substrate includes a through hole,
the first metal member is disposed in the through hole, and
at least a part of the metal compound is present on an inner wall defining the through hole.

14. The ceramic sintered body substrate according to claim 12, wherein, when a total amount of the inorganic fillers, the first metal, and the metal compound is 100 wt %, the content of the inorganic fillers is in a range from 1 wt % to 50 wt %, the content of the first metal is in a range from 40 wt % to 95 wt %, and the content of the metal compound is in a range from 1 wt % to 10 wt %.

15. The ceramic sintered body substrate according to claim 12, wherein the plurality of inorganic fillers are dispersed in the first metal that is continuous.

16. The ceramic sintered body substrate according to claim 12, wherein, in a cross-sectional view in which the first metal member disposed in the through hole is cut in a thickness direction of the ceramic substrate, the inorganic fillers are disposed in a range from 10 μm² to 75 μm² per 100 μm².

17. The ceramic sintered body substrate according to claim 13, wherein the first metal member is disposed on a flat surface and/or a bottom surface of the ceramic substrate continuously from the through hole.

18. The ceramic sintered body substrate according to claim 12, further comprising a second metal member disposed on the first metal member.

19. A light-emitting device comprising:
a ceramic sintered body substrate including a ceramic substrate and a first metal member disposed on a surface of the ceramic substrate, the first metal member containing a plurality of inorganic fillers, a first metal, and a metal compound, the metal compound being disposed on at least a part of surfaces of the plurality of inorganic fillers and at least a part of a surface of the ceramic substrate; and
a light-emitting element electrically connected to the first metal member of the ceramic sintered body substrate.

20. A light-emitting device comprising:
a ceramic sintered body substrate including a ceramic substrate and a first metal member and a second metal member disposed on a surface of the ceramic substrate, the first metal member containing a plurality of inorganic fillers, a first metal, and a metal compound, the metal compound being disposed on at least a part of surfaces of the plurality of inorganic fillers and at least a part of a surface of the ceramic substrate; and
a light-emitting element electrically connected to the first metal member or the second metal member of the ceramic sintered body substrate.
